(19) United States
(12) Patent Application Publication
(10) Pub. No.: US 2026/0287952 A1
(43) Pub. Date: Sep. 24, 2026

(54) ARRAY SUBSTRATE, DISPLAY PANEL, AND DISPLAY APPARATUS

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Yadong Zhang, Beijing (CN); Yang Li, Beijing (CN); Xiongcan Zuo, Beijing (CN); Biqi Li, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 19/477,558

(22) PCT Filed: Mar. 13, 2024
(86) PCT No.: PCT/CN2024/081510

§ 371 Date: Oct. 22, 2025

(30) Foreign Application Priority Data
Apr. 27, 2023 (CN) 202310476965.7

(51) Int. Cl. G02F 1/1362; G02F 1/1368; H10D 86/40; H10D 86/60

(52) U.S. Cl. CPC G02F 1/136286; G02F 1/136204; G02F 1/1368; H10D 86/443; H10D 86/60

(57) ABSTRACT

The present application provides an array substrate, a display panel, and a display apparatus, and relates to the technical field of displaying. The array substrate includes: a substrate; a first conductive layer located at one side of the substrate; the first conductive layer comprises an auxiliary wire; a common electrode layer, located at one side of the first conductive layer away from the substrate; the common electrode layer comprises a plurality of gate slit electrodes, the plurality of gate slit electrodes are electrically connected to the auxiliary wire through a plurality of via holes. The uniformity of the image displayed by the display panel is better. The gate slit electrodes are electrically connected with the connecting points of the auxiliary wire through a via hole, so that the auxiliary wire is connected in parallel with the common electrode layer. This reduces the resistance in the transmission path of the common voltage signal, leading to better potential uniformity among the multiple gate slit electrodes in the common electrode layer. Consequently, the uniformity of the displayed image on the display panel is improved.

### CROSS-REFERENCE TO RELATED APPLICATION

This application claims the priority of the Chinese patent application filed on Apr. 27, 2023, before the CNIPA, China National Intellectual Property Administration with the application number of 202310476965.7, and the title of “array substrate, display panel and display apparatus”, which is incorporated herein its entirety by reference.

### TECHNICAL FIELD

The present application relates to the technical field of displaying, and more particularly, to an array substrate, a display panel, and a display apparatus.

### BACKGROUND

Liquid Crystal Display (LCD) panels are widely used. The liquid crystal display panel has a problem of poor uniformity in display images.

### SUMMARY

Embodiments of the present application provide an array substrate, a display panel, and a display apparatus, which have excellent uniformity in display images.

To achieve the above object, the embodiments of the present application adopt the following technical solutions:

In one aspect, there is provided an array substrate, comprising:
a substrate;
a first conductive layer, located at one side of the substrate; wherein the first conductive layer comprises an auxiliary wire;
a common electrode layer, located at one side of the first conductive layer away from the substrate; wherein the common electrode layer comprises a plurality of gate slit electrodes, the plurality of gate slit electrodes are electrically connected to the auxiliary wire through a plurality of via holes.

In some embodiments, the common electrode layer comprises a plurality of gate slit electrode rows, the plurality of gate slit electrode rows are arranged at intervals, and each of the gate slit electrode rows comprises the plurality of gate slit electrodes; the common electrode layer further comprises a hollow area, the hollow area is located between two adjacent rows of the gate slit electrodes;

The array substrate further comprises a signal line, the signal line is arranged along an extending direction of the gate slit electrode row, and part or the whole orthographic projection area of the common electrode layer of the signal line is located in the hollow area; and the signal line comprises a data line or a scan line.

In some embodiments, the hollow area extends from one end of the gate slit electrode row to an opposite end of the gate slit electrode row.

In some embodiments, the auxiliary wire is electrically connected to a plurality of the gate slit electrode rows.

In some embodiments, the common electrode layer further comprises a connecting wire, the connecting wire is located between two adjacent gate slit electrode rows and is electrically connected to the two adjacent gate slit electrode rows.

In some embodiments, the auxiliary wire is electrically connected to a plurality of the gate slit electrode rows.

In some embodiments, further comprising a driving transistor, wherein a gate of the driving transistor is located on the first conductive layer, or a source and a drain of the driving transistor are located on the first conductive layer.

In some embodiments, part or the whole orthographic projection of the gate of the driving transistor on the common electrode layer is located within a hollow area.

In some embodiments, further comprising a scan line, the scan line includes a connecting terminal electrically connected to a gate of the driving transistor, and an orthographic projection of the connecting terminal on the common electrode layer is located within the hollow area;

the gate slit electrode comprises an lap pad, the lap pad is electrically connected to a connecting point through the via holes, and the lap pad is arranged adjacent to the connecting terminal.

In some embodiments, the plurality of gate slit electrodes are arranged at intervals, and the auxiliary wire is electrically connected to the plurality of gate slit electrodes.

In some embodiments, the gate slit electrodes comprise a frame and a plurality of electrodes connected in the frame, and a hollow area is provided between two adjacent frames.

In some embodiments, the plurality of electrodes include first electrodes extending along a first inclined direction and second electrodes extending along a second inclined direction, the first inclined direction and the second inclined direction intersect;

the first electrodes, the second electrodes and the frame together form a triangular area, and the triangular area is hollowed out.

In some embodiments, a second conductive layer and a third conductive layer are further provided between the substrate and the common electrode layer, the second conductive layer comprises a source and a drain of a driving transistor, and the third conductive layer comprises a pixel electrode.

In some embodiments, the array substrate comprises a active area, a first side, and a first non-active area located between the active area and the first side;
the first non-active area comprises a plurality of first areas arranged at intervals along the first side, and a second area located between two adjacent first areas, each of the first area is provided with a fan-out wiring or configured to bind a driving chip;
A first discharge point and a first discharge wire electrically connected to the first discharge point are arranged in the second area, the first discharge point is configured to be electrically connected to an electrostatic discharge layer of a color film substrate, and the first discharge wire is configured to be electrically connected to a second grounding wire in the control board.

In some embodiments, further comprising a first grounding wire arranged around the active area, a first end and a second end of the first grounding wire is located at the first side; two second discharge points are further arranged in the first non-active area, wherein one of the second discharge points is electrically connected to the first end of the first grounding wire, and the other of the second discharge points is electrically connected to the second end of the first grounding wire; the second discharge point is configured to be electrically connected to an electrostatic discharge layer of the color film substrate.

In some embodiments, further comprising an inner ring common voltage line and an outer ring common voltage line at least partially surrounding the active area, the outer ring common voltage line is located at one side of the inner ring common voltage line away from the active area;
a first end and a second end of the inner ring common voltage line, and a first end and a second end of the outer ring common voltage line, are located at the first side; the first and second ends of the inner ring common voltage line and the first and second ends of the outer ring common voltage line are configured to electrically connect to a common voltage line in the control board;
the first area further comprises a compensation wire, a first end of the compensation wire is electrically connected to the inner ring common voltage line, and a second end of the compensation wire is configured to be electrically connected to the common voltage line in the control board.

In another aspect, there is provided a display panel including the array substrate and a color film substrate provided oppsitely to the array substrate.

In another aspect, there is provided a display apparatus comprising the display panel.

The array substrate, the display panel and the display apparatus provided by the embodiment of the present application include a substrate, a common electrode layer and a first conductive layer positioned between the substrate and the common electrode layer, the common electrode layer includes a plurality of gate slit electrodes, the first conductive layer includes an auxiliary wire, the auxiliary wire includes a plurality of connecting points, and the gate slit electrodes are electrically connected with the connecting points of the auxiliary wire through a via hole, so that the auxiliary wire is connected in parallel with the common electrode layer. This reduces the resistance in the transmission path of the common voltage signal, leading to better potential uniformity among the multiple gate slit electrodes in the common electrode layer. Consequently, the uniformity of the displayed image on the display panel is improved.

### BRIEF DESCRIPTION OF THE DRAWINGS

To more clearly explain the technical solutions in the embodiments of the present application or the prior art, the drawings that need to be used in the description of the embodiments or the prior art will be briefly introduced below, and it is obvious that the drawings in the following description are only some embodiments of the present application, and for those skilled in the art, other drawings can be obtained according to these drawings without making creative labor.

FIG. 1 schematically shows an application scenario diagram of a display apparatus;

FIG. 2 schematically shows a partial structural diagram of a display apparatus;

FIG. 3 schematically shows a cross-sectional view of a color film substrate;

FIG. 4 schematically shows a schematic view of an array substrate;

FIG. 5 schematically shows a cross-sectional view of an array substrate;

FIG. 6 is a schematic diagram of a display panel in the related art;

FIG. 7 is a cross-sectional view along A-A in FIG. 6;

FIG. 8 is a cross-sectional view along B-B in FIG. 6;

FIG. 9 schematically shows a partial structural view of an array substrate;

FIG. 10 schematically shows a layout of a common electrode layer;

FIG. 11 schematically shows a layout of drive transistors, data lines, and scan lines in an array substrate;

FIG. 12 schematically shows a schematic diagram of a gate slit electrode;

FIG. 13 is a cross-sectional view along C-C in FIG. 9;

FIG. 14 is a cross-sectional view along D-D in FIG. 9.

### DETAILED DESCRIPTION

Hereinafter, the technical solutions in the embodiments of the present application will be clearly and completely described with reference to the accompanying drawings in the embodiments of the present application, and it is obvious that the described embodiments are only a part of the embodiments of the present application, but not all the embodiments. Based on the embodiments in the present application, all other embodiments obtained by those skilled in the art without making inventive work are within the scope of protection of the present application.

In the embodiments of the present application, words such as “first”, “second”, “third”, and “fourth” are used to distinguish the same items or similar items having basically the same functions and functions only for clearly describing the technical solutions of the embodiments of the present application, and shall not be understood as indicating or implying relative importance or implicitly indicating the quantity of indicated technical features.

In embodiments of the present application, “a plurality” means two or more, and “at least one” means one or more, unless explicitly and specifically defined otherwise.

In the embodiments of the present application, the orientation or positional relationship indicated by the terms “upper”, “lower” and the like is based on the orientation or positional relationship shown in the drawings, and is only for the convenience and simplification of the description of the present application, and does not indicate or imply that the referred device or element must have a specific orientation, be constructed and operate in a specific orientation, and therefore shall not be understood as a limitation of the present application.

Some embodiments of the present application provide a display apparatus, which may be any device that displays whether moving (e.g., video) or fixed (e.g., still image), and regardless of text or image. More specifically, the embodiments are expected to be implemented in or associated with a variety of electronic devices, such as(but not limited to) mobile phones, wireless devices, personal data assistants (PDAs), handheld or portable computers, GPS receivers/navigators, cameras, MP4 video players, video cameras, game consoles, watches, clocks, calculators, television monitors, flat panel displays, computer monitors, automotive displays (e.g., odometer displays, etc.), navigators, cockpit controllers and/or displays, camera views (e.g., displays of rear view cameras in vehicles), electronic photos, electronic billboards or signs, projectors, architectural structures, packaging, and aesthetic structures (e.g., displays for images of a piece of jewelry), etc.

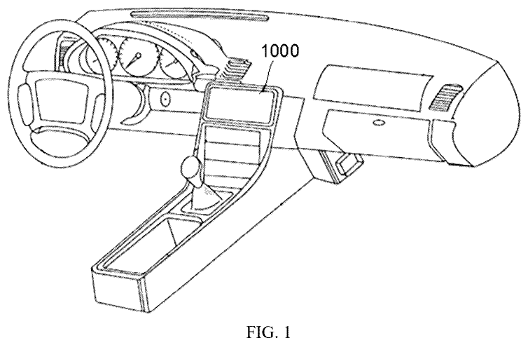

FIG. 1 schematically shows an application scenario diagram of a display apparatus. As shown in FIG. 1, the display apparatus 1000 is a center console of a vehicle, and a user interacts with the vehicle through the display apparatus 1000. For example, the display apparatus 1000 displays information of the vehicle to the user and receives an instruction from the user.

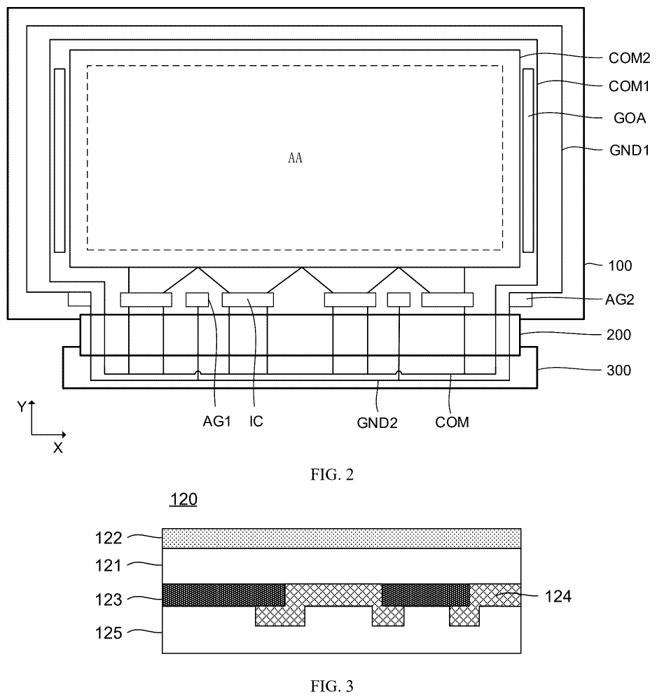

FIG. 2 schematically shows a partial structural diagram of a display apparatus. As shown in FIG. 2, the display apparatus 1000 includes a display panel 100, a flexible circuit board 200, and a control board 300.

The display panel 100 may be a Liquid Crystal Display panel (LCD), specifically, the display panel 100 may be an In-Plane Switching (IPS) Liquid Crystal Display panel. The following description is only conducted by taking the display panel 100 as an IPS liquid crystal display panel as an example.

The display panel 100 includes an array substrate 110, a color film substrate 120, and a liquid crystal. The array substrate 110 is provided oppsitely to the color film substrate 120, and the liquid crystal is positioned between the array substrate 110 and the color film substrate 120. In the actual application process, the display panel 100 may further include a touch layer. When the display panel 100 includes a touch layer, the display panel 100 may be a display panel using a non-TDDI (Touch and Display Driver Integration) technology or may be a display panel using a TDDI technology.

FIG. 3 schematically shows a cross-sectional view of a color film substrate. As shown in FIG. 3, the color film substrate 120 may include a substrate 121, an electrostatic discharge layer 122, a black matrix 123, a color filter 124, and a water blocking layer 125.

The electrostatic discharge layer 122 is located at one side of the substrate 121, the Black Matrix 123 (BM) and the color filter 124 are located at the opposite side of the substrate 121, and the water blocking layer 125 is located at the side of the Black Matrix 123 and the color filter 124 away from the substrate 121.

The electrostatic discharge layer 122 is made of a conductive material, and in order to prevent the electrostatic discharge layer 122 from affecting the light emission of the display panel 100, the electrostatic discharge layer 122 may be made of a light-transmitting conductive material. In the actual application process, the display panel 100 is provided with a first grounding wire GND1, and the electrostatic discharge layer 122 is electrically connected to the first grounding wire GND1 to discharge the collected electrostatic charge, thereby preventing the electrostatic charge from affecting the normal operation of the display panel 100. Exemplarily, the electrostatic discharge layer 122 is made of indium tin oxide (ITO).

The water blocking layer 125 is used to block external particles from entering the liquid crystal and affecting the normal operation of the display panel 100. For example, the water blocking layer 125 may be made of an inorganic material such as aluminum oxide or silicon oxide.

Exemplarily, when preparing the color film substrate 120, the electrostatic discharge layer 122 is first formed on one side of the substrate 121, then the substrate 121 is flipped, and the black matrix 123 and the color filter 124 are formed on the other side of the substrate 121, and then the water blocking layer 125 is formed on the side of the black matrix 123 and the color filter 124 away from the substrate 121.

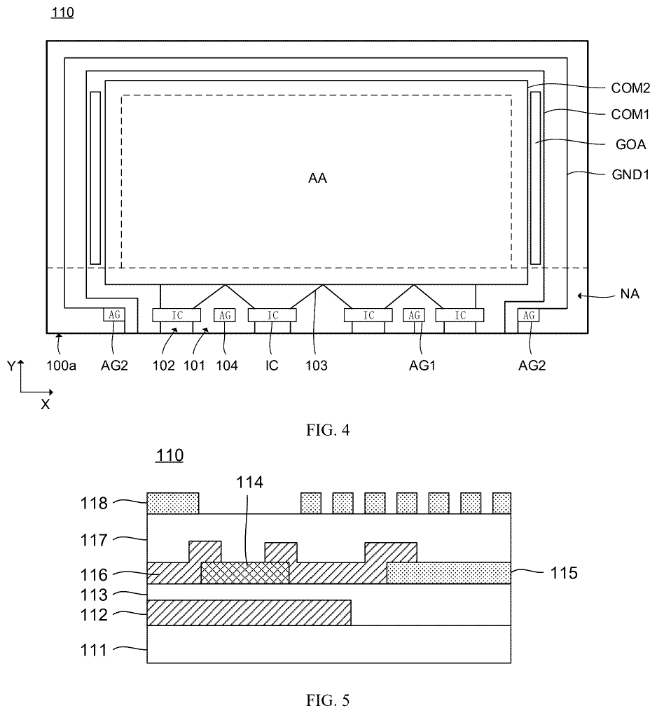

FIG. 4 shows a schematic diagram of an array substrate. As shown in FIG. 4, the array substrate 110 may have a active area AA and a non-active area connected to the active area AA. Herein, the non-active area may be located at one side, two sides, or three sides of the active area AA, or the non-active area may be arranged around the active area AA.

A binding terminal is provided in the non-active area, one end of the flexible circuit board 200 is bound to the non-active area of the array substrate 110 through the binding terminal, and the other end of the flexible circuit board 200 is electrically connected to the control board 300. During operation, the control board 300 transmits a control signal to the display panel 100 through the flexible circuit board 200, and supplies power to the display panel 100.

Exemplarily, the array substrate 110 includes a first side 100a, the non-active area includes a first non-active area NA located between the active area AA and the first side 100a, a binding terminal is provided in the first non-active area NA, and the flexible circuit board 200 is bound to the first side 100a of the array substrate 110 through the binding terminal.

The active area AA of the array substrate 110 can be equipped with a plurality of drive units, a plurality of scan lines GL, and a plurality of data lines DL.

Exemplarily, the plurality of drive units may be arranged in an array. For example, the plurality of drive unit arrays is arranged to form a plurality of drive unit rows and a plurality of drive unit columns, a plurality of drive units in one drive unit row are arranged along a first direction X, and a plurality of drive units in one drive unit column are arranged along a second direction Y.

Herein, the first direction X and the second direction Y intersect each other. The angle between the first direction X and the second direction Y can be selected and set according to actual needs. Exemplarily, the angle between the first direction X and the second direction Y may be 85 °, 88 °, 90 °, 92 °, 95 °, or the like.

The driving unit includes a gate slit electrode, a pixel electrode, and a driving transistor electrically connected to the pixel electrode. When the display panel 100 is working, the driving transistor writes a voltage signal on the pixel electrode to form an electric field between the gate slit electrode and the pixel electrode, thereby causing the liquid crystal to be deflected under the driving of the electric field.

As shown in FIG. 11, the drain D of the driving transistor TFT may be electrically connected to the pixel electrode, the source S of the driving transistor TFT may be electrically connected to the data line DL, and the gate G of the driving transistor TFT may be electrically connected to the scan line GL.

For example, the source S of the plurality of driving transistors TFTs in the same driving unit column may be electrically connected to the same data line DL, and the gate G of the plurality of driving transistors TFTs in the same driving unit row may be electrically connected to the same scan line GL.

Continuing to refer to FIG. 4, the array substrate 110 is further provided with a scan drive circuit GOA, the scan drive circuit GOA includes a plurality of cascaded shift registers, the shift register includes an output terminal, and the output terminal of the shift register may be electrically connected to the scan line GL. When the scan drive circuit GOA is working, the plurality of cascaded shift registers output scan signals cascadedly through the output terminals, enabling the plurality of drive units to be operated row by row.

Exemplarily, the scan drive circuit GOA is disposed in the non-active area.

FIG. 5 schematically shows a cross-sectional view of an array substrate. As shown in FIG. 5, the array substrate 110 includes a substrate 111 and a common electrode layer 118 located at one side of the substrate 111.

The substrate 111 may be a rigid substrate or a flexible substrate.

Exemplarily, the substrate 111 is a rigid substrate. For example, the rigid substrate may be a glass substrate, a PMMA (Polymethyl methacrylate) substrate, or the like.

Exemplarily, the substrate 111 is a flexible substrate. For example, the flexible substrate may be a polyethylene terephthalate (PET) substrate, a Polyethylene naphthalate two formic acid glycol ester (PEN) substrate, a Polyimide (PI) substrate, or the like.

The substrate 111 is used to support and protect other film layer structures of the array substrate 110, and the substrate 111 may be a single-layer structure or may be formed by stacking multilayer structures.

The common electrode layer 118 includes a plurality of g gate slit electrodes, and the common electrode layer 118 is electrically connected to the common voltage line to acquire a common voltage signal in the common voltage line and provide it to the gate slit electrode within the common electrode layer 118, enabling the gate slit electrodes to form an electric field for driving liquid crystal deflection in cooperation with the pixel electrodes.

The common electrode layer 118 is made of an electrically conductive material, and the electrically conductive material is not an ideal conductor, so that the common electrode layer 118 itself has resistance. Due to the presence of resistance, there is a potential difference between the gate slit electrode close to the common voltage line and the gate slit electrode away from the common voltage line within the common electrode layer 118, that is, the electric field between the gate slit electrode and the pixel electrode deviates, and the deviation gradually increases in the direction away from the common voltage line, resulting in poor uniformity of the image displayed on the display panel 100.

In view of this, in the embodiment of the present application, an auxiliary wire is provided in the array substrate 110, and the auxiliary wire is electrically connected to the common electrode layer 118, which is equivalent to connecting the auxiliary wire in parallel on the common electrode layer 118, thereby reducing the resistance in the transmission path of the common voltage signal, and improving the potential consistency of each gate slit electrode within the common electrode layer 118, and thus improving the uniformity of the image displayed by the display panel 100.

Specifically, as shown in FIGS. 5 and 13, a first conductive layer 112 is provided between the substrate 111 and the common electrode layer 118, the first conductive layer 112 includes an auxiliary wire SL, and a gate slit electrode within the common electrode layer 118 is electrically connected to the auxiliary wire SL through the plurality of via holes, so that the auxiliary wire SL and the common electrode layer 118 are connected in parallel.

In practical application, the auxiliary wire SL may be electrically connected to one gate slit electrode or may be electrically connected to the plurality of gate slit electrodes at the same time. When the auxiliary wire SL is electrically connected to one gate slit electrode, a plurality of connecting points of the auxiliary wire SL are electrically connected to the gate slit electrode; When the auxiliary wire SL is electrically connected to the plurality of gate slit electrodes, different connecting points may be electrically connected to different gate slit electrodes. When the auxiliary wire SL is electrically connected to the plurality of gate slit electrodes, the potentials of the plurality of gate slit electrodes can be made more uniform.

Exemplarily, the auxiliary wire SL extends from an area close to the common voltage line to an area away from the common voltage line.

The array substrate 110 provided by the embodiment of the present application includes a substrate 111, a common electrode layer 118, and a first conductive layer 112 located between the substrate 111 and the common electrode layer 118. The common electrode layer 118 includes a plurality of gate slit electrodes, and the first conductive layer 112 includes an auxiliary wire SL, and the gate slit electrodes are electrically connected to the auxiliary wire SL through a plurality of via holes. This reduces the resistance in the transmission path of the common voltage signal, leading to better potential uniformity among the multiple gate slit electrodes in the common electrode layer 118. Consequently, the uniformity of the displayed image on the display panel 100 is improved.

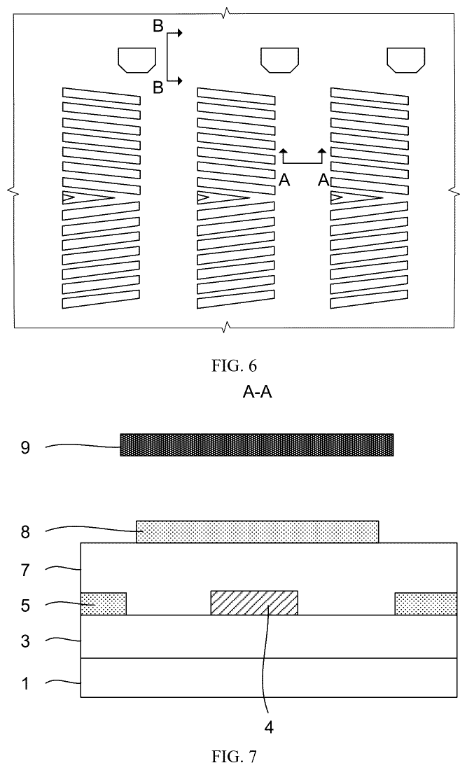

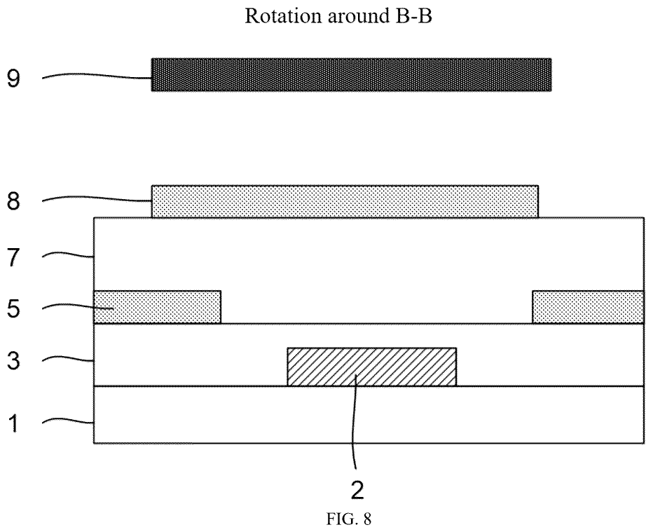

FIG. 6 is a schematic view of a display panel according to the related art, and the color film substrate is not shown in FIG. 6. FIG. 7 is a cross-sectional view along A-A in FIG. 6, and FIG. 8 is a cross-sectional view along B-B in FIG. 6. As shown in FIGS. 6 to 8, a display panel in the related art includes a substrate 1, scan lines 2, a gate insulating layer 3, data lines 4, a pixel electrode 5, an insulating layer 7, a common electrode 8, and a black matrix 9, which are stacked in sequence. As can be seen from FIG. 7, in the related art, the data lines 4 and the common electrode 8 overlap in a direction perpendicular to the substrate 1, so that a parasitic capacitance is formed between the data lines 4 and the common electrode 8, which increases the load of the common electrode 8. As can be seen from FIG. 8, the scan lines 2 and the common electrode 8 overlap in a direction perpendicular to the substrate 1, so that a parasitic capacitance is formed between the scan lines 2 and the common electrode 8, which increases the load of the common electrode 8.

Since the parasitic capacitance between the data lines 4 and the common electrode 8, and the parasitic capacitance between the scan lines 2 and the common electrode 8 increase the load of the common electrode 8. This causes an increased attenuation of the common voltage signal when transmitted in the common electrode 8, so that the potential of different positions on the common electrode 8 is different, resulting in poor uniformity of the display image of the display panel.

In view of this, in the embodiment of the present application, a hollow area may be provided in the common electrode layer 118 to reduce the parasitic capacitance formed between the common electrode layer 118 and other film layers. Moreover, since the auxiliary wire SL is connected to the common electrode layer 118, the resistance of the common electrode layer 118, after the hollow area is provided, is maintained within a reasonable range. That is, while maintaining the resistance of the common electrode layer 118 within a reasonable range, the parasitic capacitance formed by the common electrode layer 118 and other film layers is reduced. In addition, since setting the hollow area can be completed in a single photolithography process, without significant changes to the manufacturing process, production costs are reduced.

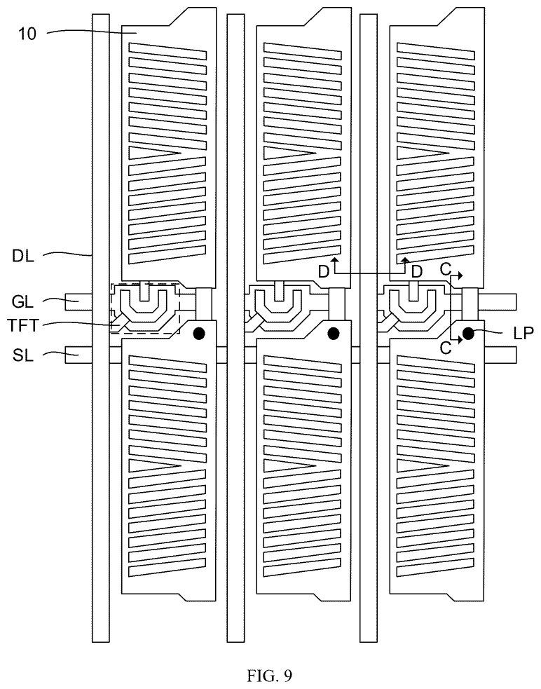

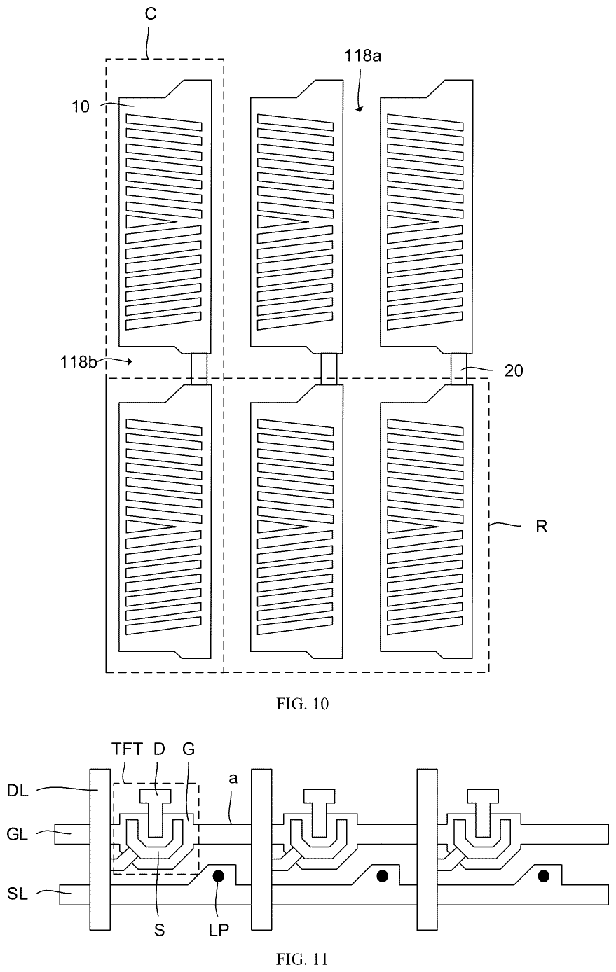

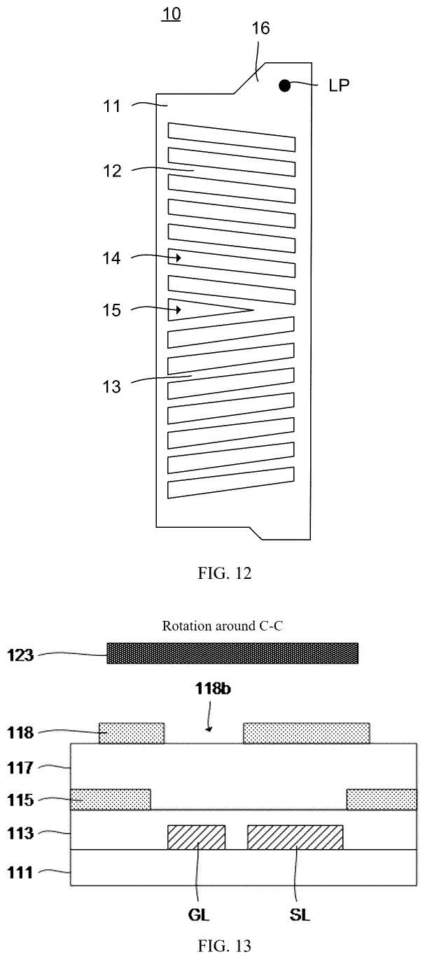

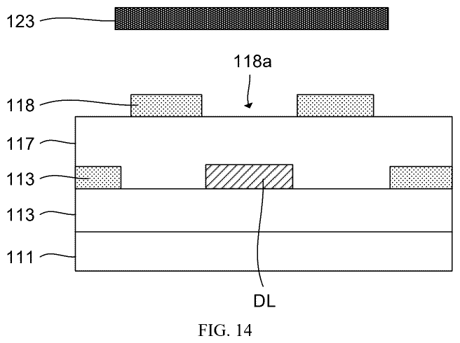

FIG. 9 schematically shows a partial structural view of an array substrate, FIG. 10 schematically shows a layout of a common electrode layer, FIG. 11 schematically shows a layout of drive transistors, data lines, and scan lines in the array substrate, FIG. 12 schematically shows a schematic view of a gate slit electrode, FIG. 13 is a cross-sectional view along C-C in FIG. 9, and FIG. 14 is a cross-sectional view along D-D in FIG. 9.

As shown in FIGS. 9 to 14, the common electrode layer 118 may include a plurality of gate slit electrode rows disposed at intervals, and each of the gate slit electrode rows includes a plurality of gate slit electrodes 10. A plurality of gate slit electrodes 10 in each row are arranged sequentially along a straight-line direction. The portion within the dashed line box shown in FIG. 10 is the gate slit electrode row. The gate slit electrode row may be a gate slit electrode column C, for example, a portion within a dashed line box extending in the vertical direction as shown in FIG. 10; The gate slit electrode row may be a gate slit electrode row R, such as the portion within a dashed line box extending in the horizontal direction as shown in FIG. 10.

It can be understood that the number of gate slit electrodes 10 included in the gate slit electrode row in FIG. 10 is only a schematic explanation due to the size of the drawing frame (the gate slit electrode row C includes two gate slit electrodes 10, and the gate slit electrode row R includes three gate slit electrodes 10), and the number of gate slit electrodes 10 included in the gate slit electrode row can be flexibly adjusted in the actual application process. For example, the display panel 100 includes a plurality of sub-pixel rows and a plurality of sub-pixel columns, and the number of gate slit electrodes 10 in the gate slit electrode row may be equal to the number of sub-pixels in the sub-pixel row or the number of sub-pixels in the sub-pixel column.

The common electrode layer 118 also includes a hollow area between two adjacent rows of gate slit electrodes. The common electrode layer 118 is made of a conductive material, and the hollow area refers to an area where the conductive material of the common electrode layer 118 is hollowed out.

Among them, the hollow area may be a conductive material in which the conductive material is completely hollowed out, that is, there is no conductive material of the common electrode layer 118 in the hollow area along the direction perpendicular to the substrate 111, and at this time, the common electrode layer 118 does not have a conductive material in the hollow area, so it does not form a parasitic capacitance with other conductive film layers.

The hollow area may also be partially hollowed out of the conductive material, that is, the thickness of the common electrode layer 118 in the hollow area is reduced in a direction perpendicular to the substrate 111. At this time, the thickness of the common electrode layer 118 in the hollow area is thin, and when the parasitic capacitance is formed with other conductive film layers, the capacitance value is small, which can also play a role in reducing the parasitic capacitance. In addition, since the conductive film layer forming a parasitic capacitance with the common electrode layer 118 is located at the side of the common electrode layer 118 facing the substrate 111, when the common electrode layer 118 is partially hollowed out, the common electrode layer 118 can be partially hollowed out along the direction in which the substrate 111 points to the common electrode layer 118, so that the distance between the remaining conductive material after hollowing out and other conductive film layers can be increased, thereby playing a role in reducing the parasitic capacitance.

The array substrate 110 further includes signal lines, the signal lines include data lines DL or scan lines GL, and the signal lines are provided along the extending direction of the gate slit electrode row.

Exemplarily, when the gate slit electrode row is a gate slit electrode column, the gate slit electrode column extends along the second direction, and at this time, the signal line may be a data line DL, and the data line DL is located between two adjacent gate slit electrode columns.

Exemplarily, when the gate slit electrode row is a gate slit electrode row, the gate slit electrode row extends along the first direction, and at this time, the signal line may be a scan line GL, and the scan line GL is located between two adjacent gate slit electrode rows.

As shown in FIG. 9, part or all of the area of the orthographic projection of the signal line on the common electrode layer 118 may be located within the hollow area.

When the entire area of the orthographic projection of the signal line on the common electrode layer 118 is located in the hollow area, there is no opposite area between the signal line and the common electrode layer 118, so that the signal line and the common electrode layer 118 do not easily form a parasitic capacitance, and reducing the load of the common voltage signal in the common electrode layer 118.

When the partial area of the signal line orthographically projected on the common electrode layer 118 is located within the hollow area, the overlapping area between the signal line and the common electrode layer 118 is reduced, thereby reducing the capacitance value of the parasitic capacitance between the signal line and the common electrode layer 118 and reducing the load of the common voltage signal in the common electrode layer 118.

The hollow area may extend along the extension direction of the signal line, thereby increasing the overlapping area of the hollow area and the signal line, and further reducing the value of the parasitic capacitance between the signal line and the common electrode layer 118.

Exemplarily, the hollow area is generally rectangular in shape, and the length direction of the hollow area is parallel to the extending direction of the signal line.

The hollow area may include a plurality of sub-hollow areas arranged at intervals.

Exemplarily, as illustrated in FIG. 10, the plurality of sub-hollow areas are arranged at intervals along the extending direction of the signal lines.

When the gate slit electrode row includes a plurality of gate slit electrode columns, a first hollow area 118a may be provided between two adjacent gate slit electrode columns; When the gate slit electrode row includes a plurality of gate slit electrode rows, a second hollow area 118b may be provided between two adjacent gate slit electrode rows; When the gate slit electrode row simultaneously includes a plurality of gate slit electrode columns and a plurality of gate slit electrode rows, the common electrode layer 118 simultaneously includes a first hollow area 118a located between two adjacent gate slit electrode columns and a second hollow area 118b located between two adjacent gate slit electrode rows.

When the common electrode layer 118 includes both the first hollow area 118a and the second hollow area 118b, the parasitic capacitance between the common electrode layer 118 and the other conductive film layers can be reduced, thereby decreasing the load of the common voltage signal.

The hollow area may extend from one end of the gate slit electrode row to the opposite other end of the gate slit electrode row. That is, the hollow area spans the area between two adjacent gate slit electrode rows along the extension direction of the gate slit electrode row, so that the two adjacent gate slit electrode rows in the common electrode layer 118 are disconnected.

Continuing to refer to FIG. 10, in the common electrode layer 118, two adjacent gate slit electrode rows are disconnected so that there is no conductive material between the two adjacent gate slit electrode rows, and when the orthographic projection of the signal line on the common electrode layer 118 is located between the two adjacent gate slit electrode rows, the overlapping area of the signal line and the common electrode layer 118 can be reduced, thereby decreasing the parasitic capacitance between the common electrode layer 118 and the signal line.

Exemplarily, the gate slit electrode row includes grid slit electrode columns and grid slit electrode rows. Within the common electrode layer 118, two adjacent gate slit electrode columns are disconnected and two adjacent gate slit electrode rows are disconnected, so that any two adjacent gate slit electrodes 10 are disconnected, that is, each gate slit electrode 10 is an island shape. This can reduce the area of the non-hollow area within the common electrode layer 118, thereby reducing the parasitic capacitance between the common electrode layer 118 and other conductive film layers.

As shown in FIG. 9, when two adjacent gate slit electrode rows are disconnected, the auxiliary wire SL may be electrically connected to the plurality of gate slit electrode rows, so that the plurality of gate slit electrode rows are electrically connected through the auxiliary wire SL, enabling each gate slit electrode to be supplied with a common voltage signal.

Exemplarily, as illustrated in FIG. 9, the auxiliary wire SL may extend in a direction perpendicular to the gate slit electrode rows such that the auxiliary wire SL overlaps with the plurality of gate slit electrode rows, and the auxiliary wire SL and the gate slit electrode rows are electrically connected through via holes in the overlapping area. Since both the auxiliary wire SL and the gate slit electrode row are supplied with a common voltage signal, that is, the potentials of the auxiliary wire SL and the gate slit electrode row are the same or substantially the same, although there is an overlapping area between the auxiliary wire SL and the gate slit electrode row, no parasitic capacitance is formed between the auxiliary wire SL and the gate slit electrode row.

Illustratively, the auxiliary wire SL is provided with a connecting point LP at a position corresponding to each gate slit electrode row, and each connecting point is electrically connected to the gate slit electrode row through a via hole.

Certainly, between the gate slit electrode row that is electrically connected to the auxiliary wire SL, there may also be a gate slit electrode row that is not electrically connected to the auxiliary wire SL.

Exemplarily, the auxiliary wire SL includes a first auxiliary sub-wire and a second auxiliary sub-wire arranged in parallel and at intervals, the first auxiliary sub-wire and the second auxiliary sub-wire are perpendicular to the gate slit electrode row, the first auxiliary sub-wire is electrically connected to the first and third gate slit electrode rows, and the second auxiliary sub-wire is electrically connected to the second and fourth gate slit electrode rows.

Certainly, the auxiliary wire SL may further include a third auxiliary sub-wire, a fourth auxiliary sub-wire, and the like, which is not limited to the embodiment of the present application.

Continuing to refer to FIG. 10, the common electrode layer 118 may further include a connecting wire 20 located between the two adjacent gate slit electrode rows and electrically connected to. The two adjacent gate slit electrode rows. Two adjacent gate slit electrode rows are connected through the connecting wire 20, so that the respective gate slit electrodes 10 within the common electrode layer 118 can be electrically connected, so that a common voltage signal can be applied to each gate slit electrode 10. In addition, the connecting wire 20 is provided between two adjacent gate slit electrode rows, which can increase the area of the conductive area in the common electrode layer 118, thereby reducing the resistance of the common electrode layer 118, and improving the uniformity of the potential of each area within the common electrode layer 118.

Herein, the number of connecting wires 20 between two adjacent gate slit electrode rows may be one or multiple, which is not limited to the embodiment of the present application.

Exemplarily, the number of connecting wires 20 between two adjacent gate slit electrode rows may be the same as the number of gate slit electrodes 10 in the gate slit electrode row, so that every two adjacent gate slit electrodes 10 in the two adjacent gate slit electrode rows may be electrically connected through the connecting wires 20.

Exemplarily, the gate slit electrode row includes a plurality of gate slit electrode rows, and two adjacent gate slit electrode rows are electrically connected through a connecting wire 20.

In practical applications, the common electrode layer 118 is typically made of a transparent conductive layer material, such as indium tin oxide (ITO), which has a high resistivity. Furthermore, to ensure the light transmittance of the common electrode layer 118, the thickness of the common electrode layer 118 is usually set to be relatively thin so that the resistance of the common electrode layer 118 is relatively large. In order to reduce the circuit of the transmission path of the common voltage signal as much as possible, this can be achieved by reducing the resistance of the auxiliary wire SL.

The conductive material for forming the gate G, the source S, and the drain D of the driving transistor TFT in the array substrate 110 is usually a metal such as copper having a low resistivity. Therefore, in order to reduce the resistance of the auxiliary wire SL, the auxiliary wire SL may be arranged in a film layer where the gate G of the driving transistor TFT is located, or the auxiliary wire SL may be arranged in a film layer where the source and drain D of the driving transistor TFT are located. That is, the gate G of the driving transistor TFT is located on the first conductive layer 112, or the source S and the drain D of the driving transistor TFT are located on the first conductive layer 112.

Illustratively, as illustrated in FIG. 9, the first conductive layer 112 includes a gate G of a driving transistor TFT, a scan line GL and an auxiliary wire SL, the scan line GL is electrically connected to the gate G of the driving transistor TFT in the same driving cell row, and the auxiliary wire SL is provided in parallel to the scan line GL, and there is a disconnection between the auxiliary wire SL and the scan line GL. In the actual application process, the spacing between the auxiliary wire SL and the scan line GL can be increased to reduce the parasitic capacitance between the auxiliary wire SL and the scan line GL.

Exemplarily, the first conductive layer 112 includes a source S of the driving transistor TFT, a drain D, a data line DL and an auxiliary wire SL, the data line DL is electrically connected to the source S of the driving transistor TFT in the same driving unit column, and the auxiliary wire SL is provided in parallel to the data line DL, and there is a disconnection between the auxiliary wire SL and the data line DL. In the actual application process, the spacing between the auxiliary wire SL and the data line DL can be increased to reduce the parasitic capacitance between the auxiliary wire SL and the data line DL.

In the driving transistor TFT, the gate G, the source S, the drain D, and the active layer 114 are all made of a conductive material, and when the common electrode layer 118 overlaps the driving transistor TFT, a parasitic capacitance is likely to be formed between the common electrode layer 118, the gate G, the source S, the drain D, and the active layer 114 of the driving transistor TFT. To reduce the parasitic capacitance between the common electrode layer 118 and the driving transistor TFT, a hollow area may be provided in the common electrode layer 118 at a position corresponding to the driving transistor TFT.

As shown in FIG. 9, part or all of the orthographic projection of the gate G of the driving transistor TFT on the common electrode layer 118 may be located in the hollow area.

Exemplarily, the entire area of the orthographic projection of the gate G of the driving transistor TFT on the common electrode layer 118 is located within the hollow area, so that there is no opposite area between the gate G of the driving transistor TFT and the common electrode layer 118, and thus parasitic capacitance is not easily formed between the gate G and the common electrode layer 118.

Exemplarily, a portion of the orthographic projection of the gate G of the driving transistor TFT on the common electrode layer 118 is located within the hollow area, so that the area of the gate G of the driving transistor TFT facing the common electrode layer 118 is reduced, thereby reducing the value of the parasitic capacitance between the gate G and the common electrode layer 118.

In the related art, to prevent the resistance of the common electrode layer 118 from increasing due to the large area of the hollow area in the common electrode layer 118, it is usually necessary to reduce the area of the hollow area as much as possible. For example, one solution in the related art is that a hollow area is provided in the common electrode layer 118 at the position corresponding to the driving transistor TFT, so that the orthographic projection of the source S and a part of the drain D of the driving transistor TFT on the common electrode layer 118 is located in the hollow area, and all or at least a part of the gate G of the driving transistor TFT still overlaps the common electrode layer 118. This makes the value of the parasitic capacitance between the common electrode layer 118 and the gate G relatively large.

In the embodiments of the present application, since the auxiliary wire SL electrically connected to the common electrode layer 118 is provided in the first conductive layer 112, the resistance of the transmission path of the common voltage signal is reduced, and thus the hollow area can be increased, so that the resistance of transmission path of the common voltage signal is kept within a reasonable range while the gate G of the driving transistor TFT overlaps the hollow area.

With continued reference to FIG. 9, since the area of the orthographic projection of the driving transistor TFT on the common electrode layer 118 is relatively large, in order to reduce the parasitic capacitance between the common electrode layer 118 and the driving transistor TFT, the size of the hollow area corresponding to the driving transistor TFT in the common electrode layer 118 is relatively large (for example, the size along the vertical direction shown in FIG. 9). With respect to the driving transistor TFT, the line width of the scanline GL is narrower, and the size of the hollow area corresponding to the scan line GL in the common electrode layer 118 (for example, the size in the vertical direction shown in FIG. 9) may be set to relatively small, so that the non-hollowed-out area of the common electrode layer 118 is increased on the basis of reducing the parasitic capacitance between the common electrode layer 118 and the scan line GL, and thereby reducing the resistance of the common electrode layer 118.

In view of this, continuing to refer to FIGS. 9 to 12, the scan line GL may include a connecting terminal electrically connected to the gate G of the driving transistor TFT, and the orthographic projection of the connecting terminal a on the common electrode layer 118 is located in the hollow area. The gate slit electrode 10 comprises an lap pad, the lap pad is electrically connected to a connecting point through the via hole, the lap pad being arranged adjacent to the connecting terminal a.

As shown in FIGS. 9 and 10, the plurality of gate slit electrodes 10 are arranged at intervals, and the auxiliary wire SL is electrically connected to the plurality of gate slit electrodes 10 so that the auxiliary wire SL is connected in parallel with the plurality of gate slit electrodes 10, thereby reducing the resistance of the common voltage transmission path. Among them, the auxiliary wire SL and the gate slit electrode 10 are electrically connected through a via hole at the LP point.

FIG. 12 shows a schematic diagram of a gate slit electrode 10. As shown in FIG. 12, the gate slit electrode 10 includes a frame 11 and a plurality of electrodes 12 connected in the frame 11, and a hollow area is provided between two adjacent frames 11. Herein, the two adjacent frames 11 refer to the frame 11 of one gate slit electrode 10 and the frame 11 of the other gate slit electrode 10 in the two adjacent gate slit electrodes 10.

The electrode 12 is used to cooperate with the pixel electrode 12 to form an electric field that drives the deflection of the liquid crystal, and a gap 14 is provided between two adjacent electrodes 12. The frame 11 is used for electrically connecting the plurality of electrodes 12. When the connecting wire 20 is provided between the two adjacent gate slit electrodes 10, the frame 11 is electrically connected to the connecting wire 20, thereby realizing the electrical connection of the two adjacent gate slit electrodes 10.

Referring to FIG. 12 again, the plurality of electrodes 12 include first electrodes 12 extending along a first inclined direction and second electrodes 13 extending along a second inclined direction, the first inclined direction and the second inclined direction intersect. The first electrodes 12, the second electrodes 13, and the frame 11 together form a triangular area 15, and the triangular area 15 is hollowed out. The hollowed-out area of the common electrode layer 118 is increased after the triangular area 15 is hollowed out, so that the light transmittance of the common electrode layer 118 is better.

Referring to FIG. 5 again, a second conductive layer 115 and a third conductive layer 116 are further provided between the substrate 111 and the common electrode layer 118, the second conductive layer 115 comprises a source S and a drain D of a driving transistor, and the third conductive layer 116 comprises a pixel electrode 12.

Exemplarily, the array substrate 110 includes a substrate 111, a first conductive layer 112, a gate G insulating layer, an active layer 114, a second conductive layer 115, a third conductive layer 116, a protective layer 117, and a common electrode layer 118. The first conductive layer 112 includes a gate G and an auxiliary wire SL of the driving transistor TFT, the second conductive layer 115 includes a source S, a drain D, and a data line DL of the driving transistor TFT, the third conductive layer 116 includes a pixel electrode 12, and the common electrode layer 118 includes a plurality of gate slit electrodes 10. The auxiliary wire SL of the first conductive layer 112 is electrically connected to the gate slit electrode 10 of the common electrode layer 118 through a via hole.

Exemplarily, the preparation process of the array substrate 110 includes: providing a substrate 111; forming a patterned first conductive layer 112 on one side of the substrate 111, the patterned first conductive layer 112 including the gate G of the driving transistor TFT and the auxiliary wire SL; A gate insulating layer 113 is formed on one side of the substrate 111 and the first conductive layer 112 away from the substrate 111; forming a patterned active layer 114 on the gate insulating layer 113; forming a patterned third conductive layer 116 (e.g., a first ITO layer) on the gate insulating layer 113, the third conductive layer 116 including the pixel electrode 12; forming a patterned second conductive layer 115 on the active layer 114 and the gate insulating layer 113, the second conductive layer 115 including a source S, a drain D and a data line DL of the driving transistor TFT, the data line DL being electrically connected to the source S; forming a protective layer 117, such as a PVX protective layer 117, on the active layer 114, the second conductive layer 115, and the third conductive layer 116; a patterned common electrode layer 118 (e.g., a second ITO layer) is formed on the protective layer 117, and the common electrode layer 118 includes a plurality of gate slit electrodes 10.

With continued reference to FIG. 4, the array substrate 110 includes a active area AA, a first side 100a, and a first non-active area NA located between the active area AA and the first side 100a. The first non-active area NA includes a plurality of first areas 102 arranged at intervals along the first side 100a and a second area 101 located between two adjacent first areas 102, the first area 102 is provided with a fan-out wiring or configured to bind a driving chip.

When the display panel 100 adopts a COG (Chip on Glass) scheme, the first area 102 is used to bind a driving chip IC; When the display panel 100 adopts a COF (Chip on Film) scheme, the first area 102 is provided with a fan-out wiring.

A first discharge point AG1 and a first discharge wire 104 electrically connected to the first discharge point AG1 are arranged in the second area 101, the first discharge point AG1 is configured to be electrically connected to an electrostatic discharge layer 122 of a color film substrate 120, and the first discharge wire 104 is configured to be electrically connected to a second grounding wire GND2 in the control board 300.

Exemplarily, the first discharge point AG1 is a silver paste dot, and the first discharge wire 104 is a silver paste line. The silver paste dot may be connected to the electrostatic discharge layer 122 of the color film substrate 120, so that the electrostatic charge in the electrostatic discharge layer 122 is sequentially discharged into the second grounding wire GND2 through the silver paste dot and the silver paste line to complete the discharge of the electrostatic charge.

By providing the first discharge point AG1 and the first discharge wire 104 in the second area 101, the electrostatic charge in the electrostatic discharge layer 122 near the second area 101 can be discharged into the second grounding wire GND2 through the first discharge point AG1 and the first discharge wire 104, thereby realizing rapid discharge of the electrostatic charge.

Exemplarily, as shown in FIG. 4, four driving chip ICs may be bonded to the array substrate 110, and the driving chip ICs include a first driving chip IC, a second driving chip IC, a third driving chip IC, and a fourth driving chip IC in a direction from left to right as shown in FIG. 4. Wherein, a first discharge point AG1 is provided between the first driving chip IC and the second driving chip IC, and a first discharge point AG1 is also provided between the third driving chip IC and the fourth driving chip IC. An identification code for identifying the type of the array substrate 110 may be provided between the second driving chip IC and the third driving chip IC.

Referring to FIG. 4 again, the array substrate 110 further includes a first grounding wire GND1 disposed around the active area AA, a first end and a second end of the first grounding wire GND1 are located at the first side 100a, and a remaining portion of the first grounding wire GND1 is disposed around the active area AA. The non-active area is also provided with two second discharge points AG2, one of which is electrically connected to the first end of the first grounding wire GND1, and the other second discharge point AG2 is electrically connected to the second end of the first grounding wire GND1. The second discharge point AG2 is configured to be electrically connected to the electrostatic discharge layer 122 of the color film substrate 120.

Herein, the first discharge point AG1 and the second discharge point AG2 may be arranged in the extending direction of the first side 100a. Exemplarily, one of the second discharge points AG2 is located in the lower left corner area of the array substrate, and the other second discharge point AG2 is located in the lower right corner area of the array substrate, so that area near the lower left corner and the lower right corner of the electrostatic discharge layer 122 can discharge electrostatic charge through the second discharge AG2. Setting the first discharge point AG1 and the second discharge point AG2 at the same time increases the discharge path of the electrostatic charge, so that the electrostatic charge can be discharged through the shortest path, thereby improving the discharge efficiency and discharge ability of the electrostatic charge.

As shown in FIG. 2, a second grounding wire GND2 may be provided in the control board 300, and the second grounding wire GND2 in the control board 300 is electrically connected to the first grounding wire GND1 in the array substrate 110 through the flexible circuit board 200, and first grounding wire GND1 and the second grounding wire GND2 form a closed loop, thereby shielding the interference of the external electric field of the closed loop to the display panel 100.

Furthermore, the second discharge point AG2 is electrically connected to the first grounding wire GND1 so that the electrostatic charge received by the second discharge point AG2 can be discharged into the second grounding wire GND2 along the first grounding wire GND1 without separately providing a trace connecting the second grounding wire GND2 and the second discharge point AG2, thereby reducing the number of traces.

Continuing to refer to FIG. 4, the array substrate 110 further includes an inner ring common voltage line COM2 and an outer ring common voltage line COM1 at least partially surrounding the active area AA, the outer ring common voltage line COM1 is located at one side of the inner ring common voltage line COM2 away from the active area AA.

Exemplarily, the outer ring common voltage line COM1 is in the shape of an inverted U, surrounding a portion of the active area AA.

Exemplarily, the inner ring common voltage line COM2 includes a first portion completely surrounding the active area AA, a first end electrically connected to the first portion and leading out to the first side 100a of the array substrate 110, and a second end electrically connected to the first portion and leading out to the first side 100a of the array substrate 110. The first end and the second end are respectively located at opposite ends of the first side 100a.

The first and second ends of the inner ring common voltage line COM2 and the outer ring common voltage line COM1 are both located at the first side 100a. As shown in FIG. 2, a common voltage line COM is provided in the control board 300, the first and second ends of the inner ring common voltage line COM2 and the first and second ends of the outer ring common voltage line COM1 are configured to electrically connect to a common voltage line COM in the control board 300 through a flexible circuit board 200.

The inner ring common voltage line COM2 and the outer ring common voltage line COM1 are electrically connected through the common voltage line COM in the control board 300, so that the inner ring common voltage line COM2 and the outer ring common voltage line COM1 are connected in parallel, thereby reducing the resistance of the transmission path of the common voltage signal and reducing the loss in the process of common voltage signal transmission.

Moreover, the outer ring common voltage line COM1 is electrically connected to the common voltage line COM in the control board 300 to form a closed-loop structure together, so that the outer ring common voltage line COM1 and the common voltage line COM in the control board 300 work together to shield an electric field outside the outer ring common voltage line COM1.

Continuing to refer to FIGS. 2 and 4, the first area 102 further includes a compensation wire 103, a first end of the compensation wire 103 is electrically connected to the inner ring common voltage line COM2, and a second end of the compensation wire 103 is configured to be electrically connected to the common voltage line in the control board 300 through flexible circuit board 200. Since the common voltage line COM in the control board 300 is electrically connected to the outer ring common voltage line COM1, the inner ring common voltage line COM2 and the outer ring common voltage line COM1 are electrically connected through the compensation wire 103, and the connection between the inner ring common voltage line COM2 and the outer ring common voltage line COM1 is increased, thereby reducing the resistance of the transmission path of the common voltage signal and reducing the loss in the process of common voltage signal transmission.

Among them, the compensation wire 103 may be directly electrically connected to the inner ring common voltage line COM2 and the common voltage line COM in the control board 300, or the compensation wire 103 may include a plurality of segments, one segment of which is electrically connected to the common voltage line COM in the control board 300 and one pin of the driving chip IC, and another segment is electrically connected to the other pin of the driving chip IC and the inner ring common voltage line COM2.

Exemplarily, when the COG solution is adopted, the compensation wire 103 comprises a plurality of segments; When the COF solution is adopted, the compensation wire 103 realizes an electrical connection between the common voltage line COM in the control board 300 and the inner ring common voltage line COM2 without passing through the driving chip IC.

For example, the outer ring common voltage line COM1 may be electrically connected to a pin of the driving chip IC through a common voltage line in the flexible circuit board 200 and the control board 300, the inner ring common voltage line COM2 is directly electrically connected to another pin of the driving chip IC, and the driving chip IC may apply different potentials to the outer ring common voltage line COM1 and the inner ring common voltage line COM2, thereby realizing compensation for the common voltage signal.

When the first discharge point AG1 is provided in the second area, the first discharge point AG1 may be located between two adjacent compensation wires 103.

Exemplarily, the first driving chip is electrically connected to the inner ring common voltage line COM2 through a first compensation wire, and the second driving chip is electrically connected to the inner ring common voltage line COM2 through a second compensation wire, wherein one of the first discharge points AG1 is located between the first compensation wire and the second compensation wire.

Exemplarily, the first compensation wire and the second compensation wire are electrically connected to the same connecting point of the inner ring common voltage line COM2 to reduce the connection resistance of the compensation wire 103 and the inner ring common voltage line COM2 and make the wiring simpler.

Exemplarily, the orthographic projection of the connection of the compensation wire 103 and the inner ring common voltage line COM2 on the first side 100a overlaps with the orthographic projection of the first discharge point AG1 on the first side 100a.

Exemplarily, the scan drive circuit GOA may be located between the inner ring common voltage line COM2 and the outer ring common voltage line COM1, so that the outer ring common voltage line COM1 protects the scan drive circuit GOA from external electric field interference, and the inner ring common voltage line COM2 prevents mutual interference between the scan drive circuit GOA and signals in the active area AA.

The above is merely a specific embodiment of the present application, but the scope of protection of the present application is not limited thereto, and any changes or substitutions that can be easily conceived by those skilled in the technical field within the technical scope disclosed by the present application should be covered within the scope of protection of the present application. Therefore, the scope of protection of the present application should be based on the scope of protection of the claims.

1. An array substrate, comprising:
a substrate;
a first conductive layer, located at one side of the substrate; wherein the first conductive layer comprises an auxiliary wire;
a common electrode layer, located at one side of the first conductive layer away from the substrate; wherein the common electrode layer comprises a plurality of gate slit electrodes, the plurality of gate slit electrodes are electrically connected to the auxiliary wire through a plurality of via holes.

2. The array substrate according to claim 1, wherein the common electrode layer comprises a plurality of gate slit electrode rows, the plurality of gate slit electrode rows are arranged at intervals, and each of the gate slit electrode rows comprises the plurality of gate slit electrodes; the common electrode layer further comprises a hollow area, the hollow area is located between two adjacent gate slit electrode rows;
the array substrate further comprises a signal line, the signal line is arranged along an extending direction of the gate slit electrode rows, and part or the whole orthographic projection area of the signal line on the common electrode layer is located in the hollow area; and the signal line comprises a data line or a scan line.

3. The array substrate according to claim 2, wherein the hollow area extends from one end of the gate slit electrode row to an opposite end of the gate slit electrode row.

4. The array substrate according to claim 3, wherein the auxiliary wire is electrically connected to the plurality of gate slit electrode rows.

5. The array substrate according to claim 2, wherein the common electrode layer further comprises a connecting wire, the connecting wire is located between two adjacent gate slit electrode rows, and is electrically connected to the two adjacent gate slit electrode rows.

6. The array substrate according to claim 1, wherein the auxiliary wire is electrically connected to a plurality of the gate slit electrode rows.

7. The array substrate according to claim 1, further comprising a driving transistor, wherein a gate of the driving transistor is located on the first conductive layer, or a source and a drain of the driving transistor are located on the first conductive layer.

8. The array substrate according to claim 7, wherein part or the whole orthographic projection of the gate of the driving transistor on the common electrode layer is located within a hollow area.

9. The array substrate according to claim 8, further comprising a scan line, wherein the scan line comprises a connecting terminal electrically connected to a gate of the driving transistor, and an orthographic projection of the connecting terminal on the common electrode layer is located within the hollow area;
the gate slit electrode comprises an lap pad electrically connected to a connecting point through the via holes, and the lap pad is arranged adjacent to the connecting terminal.

10. The array substrate according to claim 1, wherein the plurality of gate slit electrodes are arranged at intervals, and the auxiliary wire is electrically connected to the plurality of gate slit electrodes.

11. The array substrate according to claim 10, wherein the gate slit electrodes comprise a frame and a plurality of electrodes connected in the frame, and a hollow area is provided between two adjacent frames.

12. The array substrate according to claim 11, wherein the plurality of electrodes comprise first electrodes extending along a first inclined direction and second electrodes extending along a second inclined direction, the first inclined direction and the second inclined direction intersect;
the first electrodes, the second electrodes, and the frame together form a triangular area, and the triangular area is hollowed out.

13. The array substrate according to claim 1, wherein a second conductive layer and a third conductive layer are further provided between the substrate and the common electrode layer, the second conductive layer comprises a source and a drain of a driving transistor, and the third conductive layer comprises a pixel electrode.

14. The array substrate according to claim 1, wherein the array substrate comprises a active area, a first side, and a first non-active area located between the active area and the first side;
the first non-active area comprises a plurality of first areas arranged at intervals along the first side, and a second area located between two adjacent first areas, each of the first area is provided with a fan-out wiring or configured to bind a driving chip;
a first discharge point and a first discharge wire electrically connected to the first discharge point are arranged in the second area, the first discharge point is configured to be electrically connected to an electrostatic discharge layer of a color film substrate, and the first discharge wire is configured to be electrically connected to a second grounding wire in the control board.

15. The array substrate according to claim 14, further comprising a first grounding wire arranged around the active area, wherein a first end and a second end of the first grounding wire is located at the first side; two second discharge points are further arranged in the first non-active area, one of the second discharge points is electrically connected to the first end of the first grounding wire, and the other of the second discharge points is electrically connected to the second end of the first grounding wire; the second discharge point is configured to be electrically connected to an electrostatic discharge layer of the color film substrate.

16. The array substrate according to claim 15, further comprising an inner ring common voltage line and an outer ring common voltage line at least partially surrounding the active area, wherein the outer ring common voltage line is located at one side of the inner ring common voltage line away from the active area;
a first end and a second end of the inner ring common voltage line, and a first end and a second end of the outer ring common voltage line, are located at the first side; the first and second ends of the inner ring common voltage line and the first and second ends of the outer ring common voltage line are configured to electrically connect to a common voltage line in the control board;
the first area further comprises a compensation wire, a first end of the compensation wire is electrically connected to the inner ring common voltage line, and a second end of the compensation wire is configured to be electrically connected to the common voltage line in the control board.

17. A display panel, comprising the array substrate according to claim 1 and a color film substrate provided oppsitely to the array substrate.

18. A display apparatus, comprising the display panel of claim 17.

19. The display panel according to claim 17, wherein the common electrode layer comprises a plurality of gate slit electrode rows, the plurality of gate slit electrode rows are arranged at intervals, and each of the gate slit electrode rows comprises the plurality of gate slit electrodes; the common electrode layer further comprises a hollow area, the hollow area is located between two adjacent gate slit electrode rows;
the array substrate further comprises a signal line, the signal line is arranged along an extending direction of the gate slit electrode rows, and part or the whole orthographic projection area of the signal line on the common electrode layer is located in the hollow area; and the signal line comprises a data line or a scan line.

20. The display panel according to claim 19, wherein the hollow area extends from one end of the gate slit electrode row to an opposite end of the gate slit electrode row.
